(19) United States
(12) Patent Application Publication
(10) Pub. No.: US 2017/0322842 A1
(43) Pub. Date: Nov. 9, 2017

(54) MEMORY CONTROLLER, MEMORY SYSTEM, AND METHOD OF CONTROLLING MEMORY CONTROLLER

(71) Applicant: SONY CORPORATION, TOKYO (JP)

(72) Inventors: HIROYUKI IWAKI, KANAGAWA (JP); KEIICHI TSUTSUI, KANAGAWA (JP); LUI SAKAI, KANAGAWA (JP); KENICHI NAKANISHI, TOKYO (JP); HIDEAKI OKUBO, SAITAMA (JP); YASUSHI FUJINAMI, TOKYO (JP)

(21) Appl. No.: 15/529,697

(22) PCT Filed: Oct. 8, 2015
(86) PCT No.: PCT/JP2015/078609

§ 371 Date: May 25, 2017

(30) Foreign Application Priority Data
Dec. 5, 2014 (JP) 2014-246567

(51) Int. Cl. G06F 11/10; G06F 12/10; H03M 13/15

(52) U.S. Cl. CPC G06F 11/1048; H03M 13/151; G06F 12/10; G06F 2212/65

(57) ABSTRACT

Reduction in deterioration of a memory cell in a non-volatile memory is achieved. A memory controller is configured to include a time measuring unit, an elapsed time determination unit, and a read unit. The time measuring unit measures time elapsed from predetermined timing on an address where data written. The elapsed time determination unit determines whether the elapsed time exceeds a fixed amount of time upon receiving an instruction to read out the data from the address. The read control unit causes reading-out of the data from the address to pause in a case where the elapsed time is determined not to exceed the fixed amount of time.

### TECHNICAL FIELD

The present technology relates to memory controllers, memory systems, and methods of controlling the memory controller, and more particularly, to a memory controller and memory system for detecting an error, and a method of controlling the memory controller.

### BACKGROUND ART

In recent information processing systems, sometimes a non-volatile memory (NVM) has been used as an auxiliary storage device or storage. This non-volatile memory is roughly classified into flash memory compatible with data access in a large unit and non-volatile random-access memory (non-volatile RAM: NVRAM) capable of high-speed random access in a small unit. Here, a typical example of the flash memory includes NAND flash memory. On the other hand, an example of the non-volatile random-access memory includes resistive RAM (ReRAM), phase-change RAM (PCRAM), and magneto resistive RAM (MRAM).

In such non-volatile memory, it is known that a phenomenon occurs in which the characteristic value (e.g., resistance value) of a memory cell varies discontinuously over a fixed period of time due to fluctuation of the current in the memory cell. This phenomenon is called random telegraph noise, which may cause an error in written data. A memory controller that detects and corrects this error using an error detection and correction code (ECC) has been developed (e.g., see Patent Literature 1). When correction fails, the memory controller changes a threshold value to be compared with the characteristic value of the memory cell, and then reads out read data again and performs error detection and correction.

### CITATION LIST

### Patent Literature

Patent Literature 1: JP H6-110793A

### DISCLOSURE OF INVENTION

### Technical Problem

In the memory controller described above, if a variation in characteristic values due to the random telegraph noise is relatively small, an error is eliminated by changing a threshold value, thereby reading out correct data. However, in the case where the variation in characteristic values due to the random telegraph noise is large, a change in threshold values is less likely to cause the error to be eliminated. Consequently, the error fails to be correct and the data readout is repeated, and so such repetition of data readout leads to the progress of deterioration of the memory cell.

The present technology has been made in view of such situations, and an object thereof is to reduce deterioration of a memory cell in non-volatile memory.

### Solution to Problem

The present technology is devised to solve the above-described problem, and a first aspect thereof is a memory controller and a method of controlling the memory controller, the memory controller including: a time measuring unit configured to measure time elapsed from predetermined timing on an address where data is written; an elapsed time determination unit configured to determine whether the elapsed time exceeds a fixed amount of time upon receiving an instruction to read out the data from the address; and a read control unit configured to cause reading out the data from the address to pause in a case where the elapsed time is determined not to exceed the fixed amount of time. This allows reading-out of the data from the address to be paused in the case where the elapsed time is determined not to exceed the fixed amount of time.

Further, according to the first aspect, the memory controller may further include: a holding unit configured to hold the address and the elapsed time. The time measuring unit may measure the elapsed time and causes the holding unit to hold the address and the elapsed time. The elapsed time determination unit may read out the address and the elapsed time from the holding unit. This allows the address and the elapsed time to be held in the holding unit and to be read out.

Further, according to the first aspect, the time measuring unit may measure the elapsed time by setting timing of writing the data to the address as the predetermined timing. This allows the time elapsed from the timing at which the data is written to the address to be measured.

Further, according to the first aspect, the memory controller may further include: an error detection and correction unit configured to detect an error of the data read out from the address and to correct the error. The time measuring unit may issue the instruction to read out the data from the address in a case where the elapsed time exceeds the fixed amount of time. The read control unit may read out the data from the address in a case where the elapsed time is determined to exceed the fixed amount of time or a case where the time measuring unit issues the instruction to read out the data. The time measuring unit may measure the elapsed time by setting the timing of writing the data to the address or timing at which the error fails to be corrected as the predetermined timing. This allows reading-out of the data from the address to be instructed when the elapsed time exceeds the fixed amount of time.

Further, according to the first aspect, the memory controller may further include: an error detection and correction unit configured to detect an error of the data read out from the address and to correct the error. The time measuring unit may measure the elapsed time by setting the timing at which the error fails to be corrected as the predetermined timing. This allows the time elapsed from the timing at which the error correction fails to be measured.

Further, according to the first aspect, the time measuring unit may issue the instruction to read out the data from the address in a case where the elapsed time exceeds the fixed amount of time. The read control unit may read out the data from the address in a case where the elapsed time is determined to exceed the fixed amount of time or a case where the time measuring unit issues the instruction to read out the data. This allows reading-out of the data from the address to be instructed when the elapsed time exceeds the fixed amount of time.

Further, according to the first aspect, the memory controller may further include: a read-error output unit configured to output a read error in the case where the elapsed time is determined not to exceed the fixed amount of time. This allows the read error to be output in the case where the elapsed time is determined not to exceed the fixed amount of time.

Further, a second aspect of the present technology is a memory system including: a memory cell having an address assigned to the memory cell; a time measuring unit configured to measure time elapsed from predetermined timing on the address where data is written; an elapsed time determination unit configured to determine whether the elapsed time exceeds a fixed amount of time upon receiving an instruction to read out the data from the address; and a read control unit configured to cause reading out the data from the address to pause in a case where the elapsed time is determined not to exceed the fixed amount of time. This allows reading-out of the data from the address to be paused in the case where the elapsed time is determined not to exceed the fixed amount of time.

### Advantageous Effects of Invention

The present technology can give an excellent effect of reducing the deterioration of a memory cell in a non-volatile memory. Note that the effects described above are not necessarily limitative, and any of the effects described in the present disclosure may be applied.

### BRIEF DESCRIPTION OF DRAWINGS

FIG. 1 is an overall view illustrating a configuration example of a memory system according to a first embodiment.

FIG. 2 is a block diagram illustrating a configuration example of a memory controller according to the first embodiment.

FIG. 3 is a block diagram illustrating a functional configuration example of the memory controller according to the first embodiment.

FIG. 4 is a block diagram illustrating a configuration example of a read control unit according to the first embodiment.

FIG. 5 is a diagram illustrating an example of a read-out pause list according to the first embodiment.

FIG. 6 is a block diagram illustrating a configuration example of a non-volatile memory according to the first embodiment.

FIG. 7 is a diagram illustrating an example of resistance distribution of a variable resistance element according to the first embodiment.

FIG. 8 is a graph showing an example of a variation in the resistance values and deterioration degree of a memory cell with the lapse of time in the first embodiment.

FIG. 9 is a flowchart illustrating an example of an operation of the memory controller according to the first embodiment.

FIG. 10 is a flowchart illustrating an example of write processing according to the first embodiment.

FIG. 11 is a flowchart illustrating an example of read processing according to the first embodiment.

FIG. 12 is a flowchart illustrating an example of time measuring processing according to the first embodiment.

FIG. 13 is a sequence diagram illustrating an example of an operation of the memory system according to the first embodiment.

FIG. 14 is a block diagram illustrating a functional configuration example of a memory controller according to a second embodiment.

FIG. 15 is a flowchart illustrating an example of time measuring processing according to the second embodiment.

FIG. 16 is a flowchart illustrating an example of an operation of the memory controller according to the second embodiment.

FIG. 17 is a flowchart illustrating an example of read processing according to the second embodiment.

FIG. 18 is a sequence diagram illustrating an example of an operation of a memory system according to the second embodiment.

FIG. 19 is a block diagram illustrating a functional configuration example of a memory controller according to a third embodiment.

FIG. 20 is a flowchart illustrating an example of write processing according to the third embodiment.

FIG. 21 is a flowchart illustrating an example of read processing according to the third embodiment.

FIG. 22 is a graph showing an example of a variation in the resistance values and deterioration degree of a memory cell with the lapse of time in the third embodiment.

FIG. 23 is a sequence diagram illustrating an example of an operation of a memory system according to the third embodiment.

FIG. 24 is a block diagram illustrating a functional configuration example of a memory controller according to a fourth embodiment.

FIG. 25 is a flowchart illustrating an example of read processing according to the fourth embodiment.

FIG. 26 is a sequence diagram illustrating an example of an operation of a memory system according to the fourth embodiment.

### MODE(S) FOR CARRYING OUT THE INVENTION

A best mode for carrying out the present technology (hereinafter referred to as embodiment) is described below. The description is given in the following order.
1. First embodiment (example of reading out data after lapse of fixed amount of time from writing)
2. Second embodiment (example of issuing command and reading out data after lapse of fixed amount of time from writing)
3. Third embodiment (example of reading out data after lapse of fixed amount of time from occurrence of read error)
4. Fourth embodiment (example of issuing command and reading out data after lapse of fixed amount of time from occurrence of read error)

### 1. First Embodiment

### [Configuration Example of Memory System]

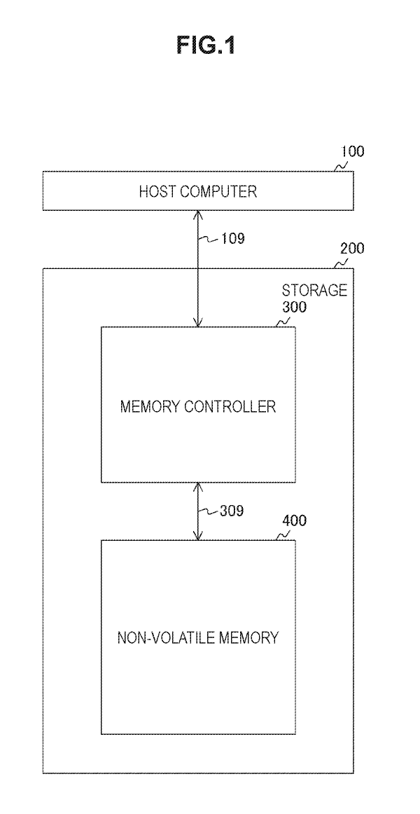

FIG. 1 is an overall view illustrating a configuration example of a memory system according to an embodiment of the present technology. This memory system is configured to include a host computer 100 and storage 200.

The host computer 100 controls the entire information processing system. The host computer 100 generates a command and data, and supplies them to the storage 200 via a signal line 109. In addition, the host computer 100 receives the read-out data from the storage 200. Here, the command is used to control the storage 200, and includes, for example, a write command used to instruct data to be written and a read command used to instruct data to be read out.

The storage 200 is configured to include a memory controller 300 and a non-volatile memory 400. The memory controller 300 controls the non-volatile memory 400. The memory controller 300, when receiving a write command and data from the host computer 100, generates an ECC from the received data. More specifically, the memory controller 300 converts (i.e., encodes) encoding target data into a code word including the data and its parity. The memory controller 300 accesses the non-volatile memory 400 via a signal line 309 and writes the encoded data as write data.

Further, the memory controller 300, when receiving a read command from the host computer 100, accesses the non-volatile memory 400 via the signal line 309 and reads out encoded read data. Then, the memory controller 300 converts (i.e., decodes) the read data into the original data before encoding. In addition, at the time of decoding, the memory controller 300 detects and corrects an error in the read data on the basis of the ECC. The memory controller 300 supplies the corrected original data to the host computer 100.

The non-volatile memory 400 stores data under the control of the memory controller 300. In one example, ReRAM is used as the non-volatile memory 400. The non-volatile memory 400 is composed of a plurality of memory cells, and these memory cells are divided into a plurality of blocks. Here, the block is an access unit of the non-volatile memory 400, and is also called a sector. A physical address is assigned to each of the blocks. Moreover, as the non-volatile memory 400, flash memory, PCRAM, MRAM, or the like may be used, instead of the ReRAM.

### [Configuration Example of Memory Controller]

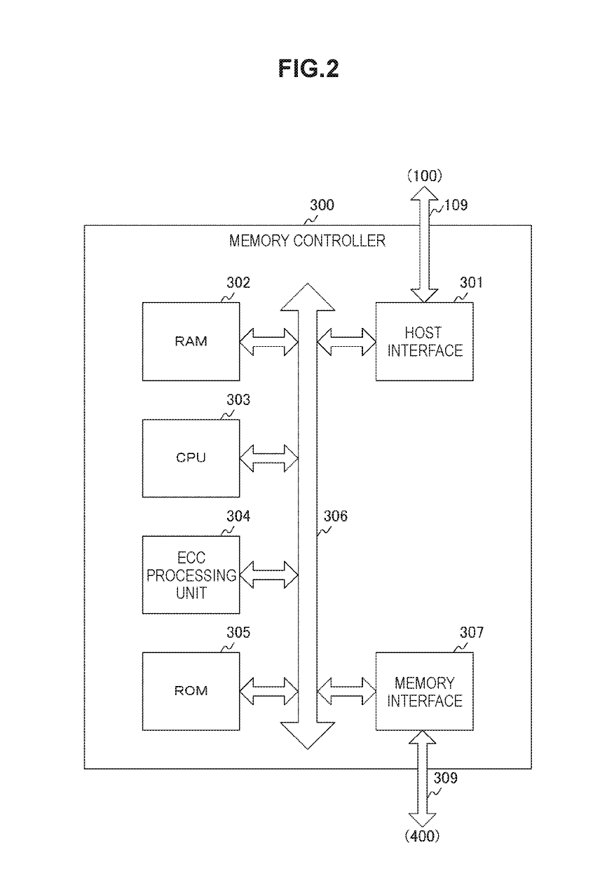

FIG. 2 is a block diagram illustrating a configuration example of the memory controller 300 according to the first embodiment. The memory controller 300 is configured to include a host interface 301, random-access memory (RAM) 302, a central processing unit (CPU) 303, and an ECC processing unit 304. The memory controller 300 is also configured to include read-only Memory (ROM) 305, a bus 306, and a memory interface 307.

The host interface 301 exchanges data and a command with the host computer 100. The RAM 302 temporarily holds data necessary for processing executed by the CPU 303. The CPU 303 controls the entire memory controller 300. The ROM 305 stores a program or the like executed by the CPU 303. The bus 306 is a common path that enables the RAM 302, the CPU 303, the ECC processing unit 304, the ROM 305, the host interface 301, and the memory interface 307 to exchange data among them. The memory interface 307 exchanges data and a command with the non-volatile memory 400.

The ECC processing unit 304 encodes data or decodes read data. In encoding data, the ECC processing unit 304 encodes encoding target data in a predetermined unit by adding parity to the data. Then, the ECC processing unit 304 supplies the encoded data for using as write data to the non-volatile memory 400 via the bus 306.

Further, the ECC processing unit 304 decodes the encoded read data into the original data. In decoding, the ECC processing unit 304 detects whether there is an error in the read data by using the parity and, if any, corrects it. The ECC processing unit 304 supplies the decoded original data to the host computer 100 via the bus 306.

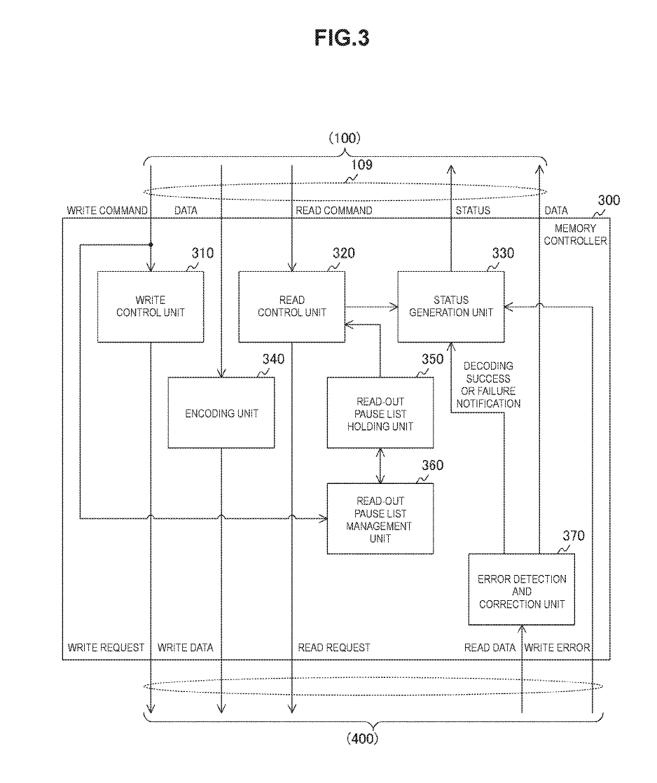

FIG. 3 is a block diagram illustrating a functional configuration example of the memory controller 300 according to the first embodiment. The memory controller 300 is configured to include a write control unit 310, a read control unit 320, a status generation unit 330, an encoding unit 340, a read-out pause list holding unit 350, a read-out pause list management unit 360, and an error detection and correction unit 370. The write control unit 310 is implemented by the host interface 301, the RAM 302, the CPU 303, the ROM 305, the bus 306, the memory interface 307, or the like shown in FIG. 2. The same applies to the read control unit 320, the status generation unit 330, and the read-out pause list management unit 360. In addition, the encoding unit 340 and the error detection and correction unit 370 are implemented by the ECC processing unit 304 shown in FIG. 2. In addition, the read-out pause list holding unit 350 is implemented by the RAM 302 or the like shown in FIG. 2.

The write control unit 310 causes the write data to be written to the non-volatile memory 400 in accordance with the write command. The write control unit 310 converts a logical address designated by the write command into a physical address.

Here, the logical address is an address assigned for each access unit area when the host computer 100 accesses the storage 200 in the address space defined by the host computer 100. This logical address is also called a page address. In addition, the physical address is an address assigned for each access unit in the non-volatile memory 400 as described above.

Further, the write control unit 310 divides the write command in the case where the host computer 100 and the non-volatile memory 400 are different in access units. The write control unit 310 converts the logical address into the physical address, and supplies each of the write commands divided depending on necessity to the non-volatile memory 400 as a write request.

The encoding unit 340, when receiving data from the host computer 100 as encoding target data, encodes the encoding target data into a code word. In encoding, the encoding target data is encoded into, for example, a binary BCH code. The encoding unit 340 supplies the code word to the non-volatile memory 400 as write data.

Moreover, although the encoding unit 340 encodes the encoding target data into the binary BCH code, the encoding unit 340 may encode it into a code other than the BCH code as long as the code can be a target subjected to error correction processing. The encoding unit 340 may encode it into, for example, the Reed-Solomon (RS) or convolutional code. In addition, the encoding unit 340 may encode it into a code having a dimension higher than binary.

The read-out pause list management unit 360 measures time elapsed from the timing at which data is written to the address. The read-out pause list management unit 360 measures the time elapsed from the timing at which the data is written for each logical address (page address) designated by the write command. Then, the read-out pause list management unit 360 causes the read-out pause list holding unit 350 to hold the list, which includes an address where the data is written and the elapsed time for each address, as a “read-out pause list”. In addition, if the elapsed time exceeds a fixed amount of time, the read-out pause list management unit 360 deletes a logical address, which corresponds to the elapsed time, from the read-out pause list. Here, a fixed amount of time Tp equal to or more than time Tr that is no longer expected to occur the RTN error after the data is written is set as the fixed amount of time. Moreover, the read-out pause list management unit 360 is an example of a time measuring unit recited in the claims. In addition, the read-out pause list holding unit 350 is an example of a holding unit recited in the claim.

Moreover, although the read-out pause list management unit 360 causes the read-out pause list holding unit 350 to hold the elapsed time for each logical address (page address), the read-out pause list management unit 360 may cause it to hold the elapsed time for each physical address. In addition, although the read-out pause list management unit 360 causes the elapsed time to be held for each address, the elapsed time may be held for each group including a plurality of addresses. In one example, in the case where a plurality of physical addresses correspond to one logical address, the identical measured time is held in association with these physical addresses.

The read control unit 320 causes the non-volatile memory 400 to read out the read data in accordance with the read command. The read control unit 320 determines whether the logical address designated by the read command is held in the read-out pause list holding unit 350. In the case where the logical address is not held in the read-out pause list (i.e., the elapsed time exceeds the fixed amount of time Tp), the read control unit 320 issues a read request from the read command and supplies it to the non-volatile memory 400. On the other hand, in the case where the elapsed time is equal to or less than the fixed amount of time Tp, the read control unit 320 causes reading-out of data from the address to pause. In addition, the read control unit 320 notifies the status generation unit 330 of a determination result as to whether the elapsed time is equal to or less than the fixed amount of time Tp.

The error detection and correction unit 370 receives the reception word, which corresponds to the code word from the non-volatile memory 400, as read data, and decodes the read data. The error detection and correction unit 370 performs error detection and correction of the read data in decoding, and supplies a decoding success or failure notification, which indicates whether the error correction is successful, to the status generation unit 330. In addition, the error detection and correction unit 370 supplies the decoded original data to the host computer 100.

The status generation unit 330 generates status information used to notify the status of the storage 200. The status generation unit 330, when receiving a write error from the non-volatile memory 400, generates the status information having the write error described therein. In addition, the status generation unit 330, when receiving the decoding success or failure notification indicating that the error correction fails from the error detection and correction unit 370, generates status information having a read error described therein. Furthermore, even when the status generation unit 330 receives a determination result indicating that the elapsed time is equal to or less than the fixed amount of time Tp from the read control unit 320, the status generation unit 330 generates the status information having the read error described therein likewise. The status generation unit 330 supplies the generated status information to the host computer 100. Moreover, the status generation unit 330 is an example of a read-error output unit recited in the claim.

Moreover, the status generation unit 330 generates the status information having the read error described therein in the case where the elapsed time is equal to or less than the fixed amount of time Tp, but the status generation unit 330 is not limited to this configuration. In one example, the status generation unit 330 may generate status information having “busy” described therein in the case where the elapsed time is equal to or less than the fixed amount of time Tp.

Further, although the status generation unit 330 outputs without distinguishing between the read error generated in response to the failure of the error correction and the read error generated without the error correction, the status generation unit 330 may output the status having the type of these read errors described therein. In this case, in one example, the former read error is output as an ECC error, and the latter read error is output as a non-ECC error. In addition, in the case of the non-ECC error, the host computer 100 sets the time taken until the re-issuance of the read command to be longer than in the case of the ECC error.

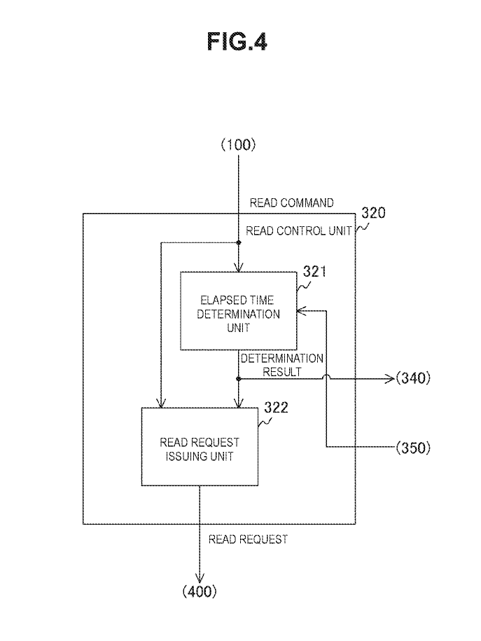

FIG. 4 is a block diagram illustrating a configuration example of the read control unit 320 according to the first embodiment. The read control unit 320 is configured to include an elapsed time determination unit 321 and a read request issuing unit 322.

The elapsed time determination unit 321 determines whether the elapsed time, which corresponds to the address in which reading-out of data is designated, exceeds the fixed amount of time Tp. The elapsed time determination unit 321 determines whether the logical address designated by the read command is held in the read-out pause list holding unit 350 (i.e., the elapsed time exceeds the fixed amount of time Tp). The elapsed time determination unit 321 supplies the determination result to the read request issuing unit 322 and the status generation unit 330.

In the case where the elapsed time exceeds the fixed amount of time Tp, the read request issuing unit 322 converts a logical address designated by the read command into a physical address and issues a write request by dividing it as necessary. On the other hand, if the elapsed time is equal to or less than the fixed amount of time Tp, the read request issuing unit 322 does not issue a read request. In other words, issuance of the read request pauses. In the case where the fixed amount of time Tp is not elapsed, the RTN error is likely to occur, which leads to the deterioration of the memory cell due to unnecessary read access. Moreover, the read request issuing unit 322 is an example of a read unit recited in the claims.

### [Example of Read-Out Pause List]

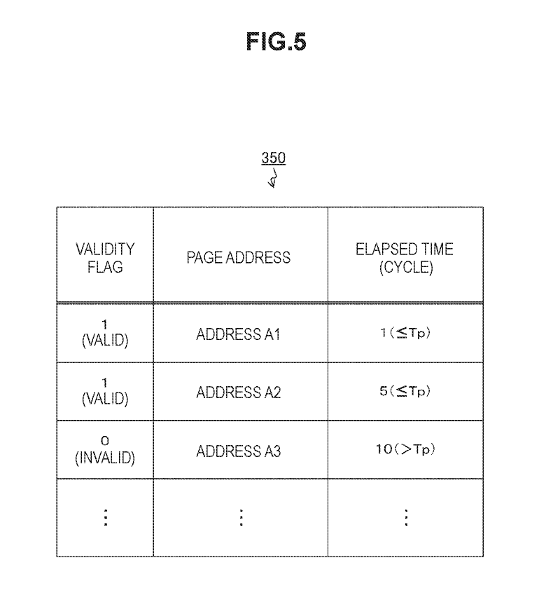

FIG. 5 is a diagram illustrating an example of a read-out pause list according to the first embodiment. The read-out pause list has a predetermined number of entries provided therein, each including a validity flag, a page address, and elapsed time. The validity flag is a flag indicating whether the corresponding page address is valid. In one example, the validity flag is set to “1” in the case where the page address is valid, and the validity flag is set to “0” in the case where the page address is invalid.

Further, the elapsed time is the time elapsed from the timing at which data is written to the corresponding page address. The unit of the elapsed time is, for example, the number of cycles of the clock signal of a fixed frequency. When a write command is issued, the read-out pause list management unit 360 registers the page address designated by the write command in the vacant entry whose validity flag is “0” in the read-out pause list. The validity flag of the registered page address is updated to “1”. In addition, the read-out pause list management unit 360 resets the elapsed time of the registered page address to the initial value, and increments the value in synchronization with a predetermined clock signal. Then, when the elapsed time exceeds the fixed amount of time Tp, the read-out pause list management unit 360 updates the validity flag of the page address corresponding to the elapsed time to “0”, and invalidates the address.

Moreover, although the read-out pause list management unit 360 is configured to measure the time elapsed from the timing at which the data is written, the read-out pause list management unit 360 may measure the remaining time until the fixed amount of time Tp elapses from the timing. In this case, the number of cycles corresponding to the fixed amount of time Tp is set as the initial value of the remaining time, and the cycle number is decremented in synchronism with the clock signal.

### [Configuration Example of Non-Volatile Memory]

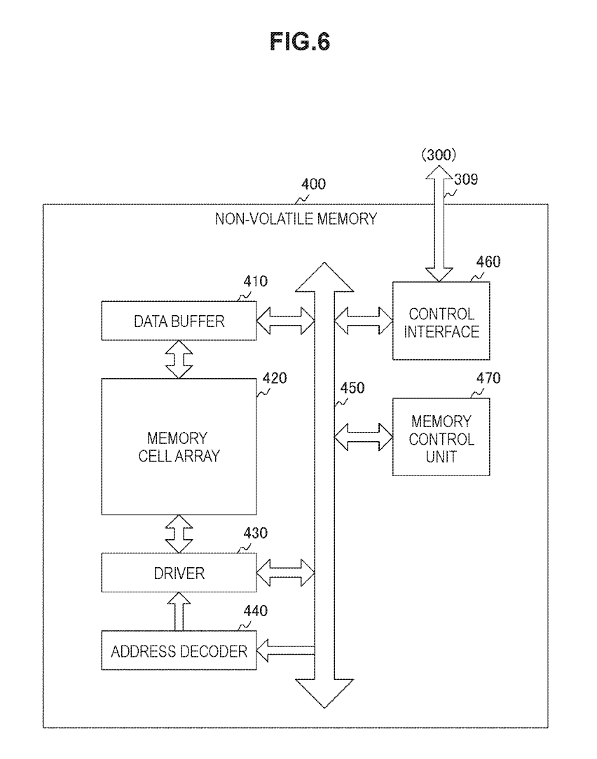

FIG. 6 is a block diagram illustrating a configuration example of the non-volatile memory 400 according to the first embodiment. The non-volatile memory 400 is configured to include a data buffer 410, a memory cell array 420, a driver 430, an address decoder 440, a bus 450, a control interface 460, and a memory control unit 470.

The data buffer 410 holds write data or read data in the units of access under the control of the memory control unit 470. The memory cell array 420 is composed of a plurality of memory cells arranged in a matrix. A non-volatile storage element is used as each of the memory cells. Specifically, NAND or NOR flash memory, ReRAM, PCRAM, MRAM, or the like is used as a storage element.

The driver 430 writes or reads data to or from the memory cell selected by the address decoder 440. The address decoder 440 analyzes an address designated by a command and selects a memory cell corresponding to the address. The bus 450 is a common path that enables the data buffer 410, the memory cell array 420, the address decoder 440, the memory control unit 470, and the control interface 460 to exchange data among them. The control interface 460 is an interface that enables the memory controller 300 and the non-volatile memory 400 to exchange data and commands between them.

The memory control unit 470 controls the driver 430 and the address decoder 440 so that they may perform writing or reading-out of data. The memory control unit 470, when receiving the write command and the write data, writes the write data to the write address designated by the command. After the writing, the memory control unit 470 reads out data from the write address as verify-read data, and performs verify processing for comparing the verify-read data and the write data in the units of bit. In the case where none of the bits of the verify-read data and the write data coincides, the memory control unit 470 detects the verify-error, writes the write data again, and performs the verify processing again. Then, in the case where the verify error is not eliminated by performing the verify processing a predetermined number of times, the memory control unit 470 outputs the write error to the memory controller 300.

The memory control unit 470, when receiving the read command, controls the address decoder 440 and the driver 430 so that they may output the data of the designated physical address to the memory controller 300 as read data.

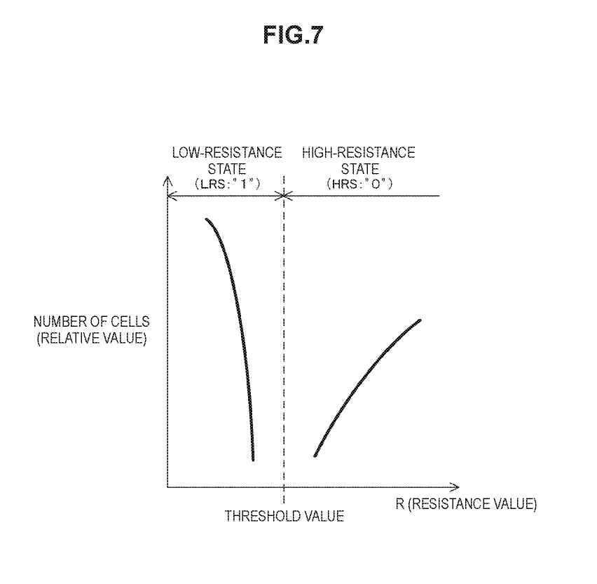

FIG. 7 is a diagram illustrating an example of the resistance distribution of the variable resistance element according to the first embodiment. In this figure, the horizontal axis represents the resistance value R, and the vertical axis represents the relative distribution of the number of cells by a relative value. The resistance state of the variable resistance element is roughly divided into two distributions with a predetermined threshold value as a boundary. The state in which the resistance value is lower than the threshold value is called a low-resistance state (LRS), and the state in which the resistance value is higher than the threshold value is called a high-resistance state (HRS).

The variable resistance element functions as a memory cell by associating the high-resistance state and the-low resistance state of the variable resistance element with either a logical value 0 or a logical value 1. The association of the states with either the logical value 0 or the logical value 1 is performed optionally. In one example, the high-resistance state is associated with the logical value 0, and the low-resistance state is associated with the logical value 1. In addition, the deterioration of the memory cell is in progress for each read access, and its resistance value slightly varies. In one example, as the deterioration is in progress, the resistance value increases. The phenomenon that the memory cell deteriorates due to the repetition of access as described above is called read disturb.

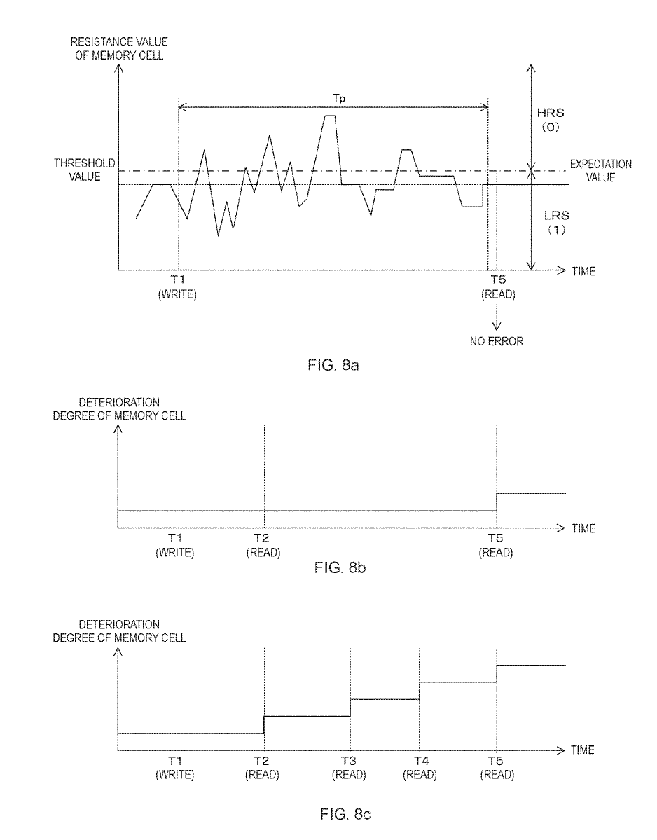

FIG. 8 is a graph showing an example of a variation in resistance values and deterioration degree of a memory cell with the lapse of time in the first embodiment. In the portion a of this figure is a graph showing an example of a variation in resistance values of the memory cell with the lapse of time. In the portion a of this figure, the vertical axis represents the resistance value of the memory cell, and the horizontal axis represents time.

In one example, consider a case where a value of “1” is written to a memory cell at timing T1. In the configuration in which “1” is assigned to LRS, the writing causes the resistance value of the memory cell to be lower than a threshold value. However, during the period from the writing to the lapse of a fixed amount of time, the resistance value irregularly varies due to fluctuation of the current in the memory cell. This phenomenon is called random telegraph noise. The resistance value varies discontinuously during the period in which this random telegraphic noise occurs, and thus it is more likely to fail to perform the reading-out of the value of the read data accurately.

Here, the random telegraph noise is typically eliminated when the predetermined time Tr elapses, and the resistance value of the memory cell becomes a fixed expectation value. The time that is equal to or more than the time Tr is set to Tp. When the read command is received before the time elapsed from the timing T1 exceeds Tp, the memory controller 300 returns the status of the read error to the host computer 100, without performing the read access to the memory cell.

On the other hand, when the read command is received at the timing T5 in which the elapsed time exceeds Tp, the memory controller 300 reads out the read data from the memory cell and decodes it. At the timing T5, the random telegraph noise is eliminated, and thus no error is detected.

The portion b of FIG. 8 is a graph showing an example of a variation in the deterioration degree of the memory cell with the lapse of time in the first embodiment. In the portion b of this figure, the vertical axis represents the deterioration degree of the memory cell, and the horizontal axis represents time. When the read data is read out at the timing T5 after the lapse of Tp, deterioration is in progress and the deterioration degree increases. During the period from the timing T1 to the timing T5, no read access is performed and so the deterioration is not in progress.

The portion c of FIG. 8 is a graph showing an example of a variation in the deterioration degree of the memory cell with the lapse of time as a comparative example. In the portion c of this figure, the vertical axis represents the deterioration degree of the memory cell and the horizontal axis represents time. In this comparative example, it is assumed that the memory controller 300 reads the read data even before the elapsed time from the timing T1 at which the data is written exceeds Tp. In this comparative example, the read data is read out again at the timings T2, T3 and T4 between the timing T1 and the lapse of Tp.

At these timings T2, T3, and T4, the random telegraph noise remain, so the resistance value of the memory cell does not become an expectation value, and an error beyond the threshold value is often detected. This error may cause failed error correction. Consequently, the memory controller 300 can read out accurately the data at the timing T5, but, before the timing T5, unnecessary read access that is incapable of eliminating an error is likely to be repeated. Such unnecessary read access increases the deterioration degree of the memory cell as compared with the case of the portion b of this figure.

As exemplified by the portion c in FIG. 8, the configuration in which the read access is performed even during the period in which the random telegraphic noise occurs causes the read access to be repeated more than necessary until accurate data is finally read out. Thus, the lifetime of the memory cell will be shortened due to read disturb. On the other hand, as exemplified by the portion b in this figure, in the memory controller 300 in which the read access is paused during the period in which the random telegraphic noise occurs, it is possible to reduce the progress of deterioration of the memory cell due to read disturb. Thus, the lifetime of the memory cell can be extended.

### [Example of Operation of Memory Controller]

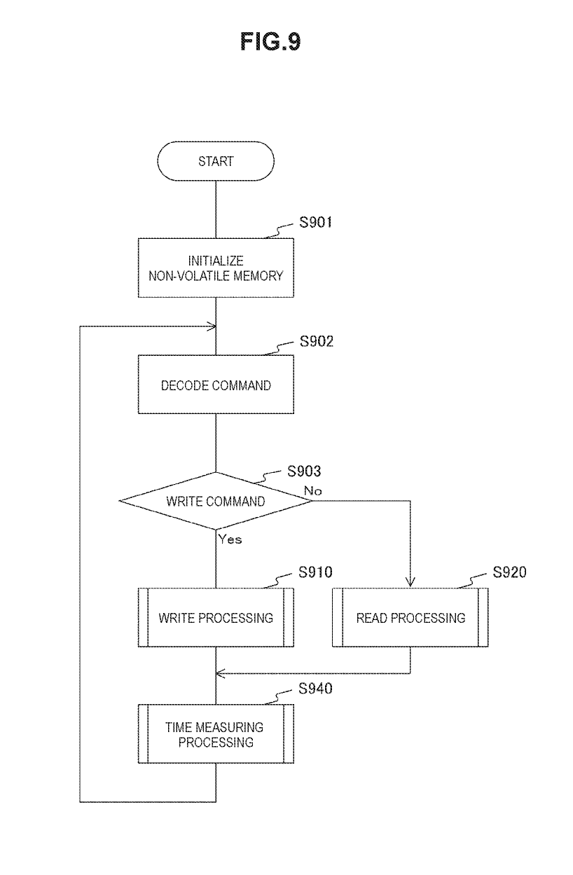

FIG. 9 is a flowchart illustrating an example of the operation of the memory controller 300 according to the first embodiment. This operation starts, for example, when the memory controller 300 is powered on or when the non-volatile memory 400 is instructed to be initialized.

The memory controller 300 initializes the non-volatile memory 400 (step S901), and decodes a command from the host computer 100 (step S902). The memory controller 300 determines whether the command is a write command (step S903). If the command is a write command (Yes in step S903), the memory controller 300 performs write processing for writing data (step S910). On the other hand, if the command is a read command (No in step S903), the memory controller 300 performs read processing for reading out data (step S920). Subsequent to step S910 or S920, the memory controller 300 performs time measuring processing for measuring the elapsed time for each address (step S940), and returns to step S902.

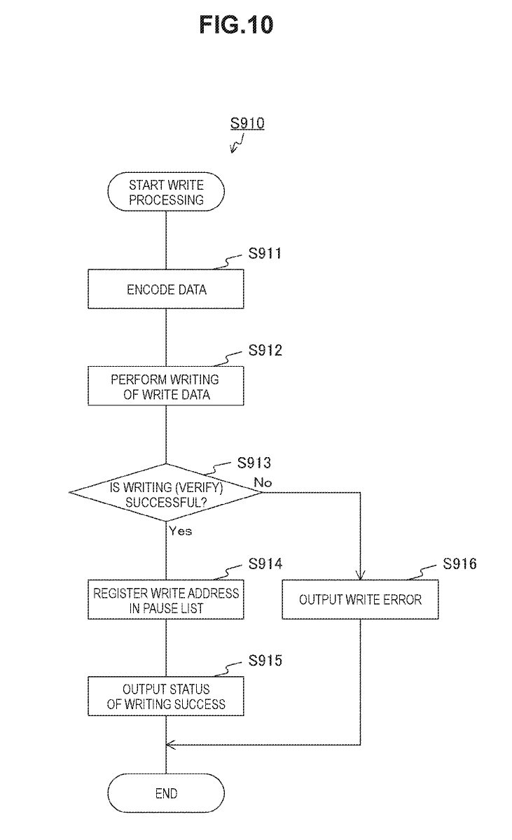

FIG. 10 is a flowchart illustrating an example of the write processing according to the first embodiment. The memory controller 300 encodes the data to generate write data (step S911) and causes the write data to be written to the non-volatile memory 400 (step S912). The memory controller 300 determines whether the non-volatile memory 400 succeeds in writing (i.e., verify) (step S913). If the writing is successful (Yes in step S913), the memory controller 300 registers the write address in the read-out pause list (step S914). In addition, the memory controller 300 outputs a status indicating that the writing is successful to the host computer 100 (step S915).

On the other hand, if the writing fails (No in step S913), the memory controller 300 outputs the status of the write error to the host computer 100 (step S916). Subsequent to step S915 or S916, the memory controller 300 ends the write processing.

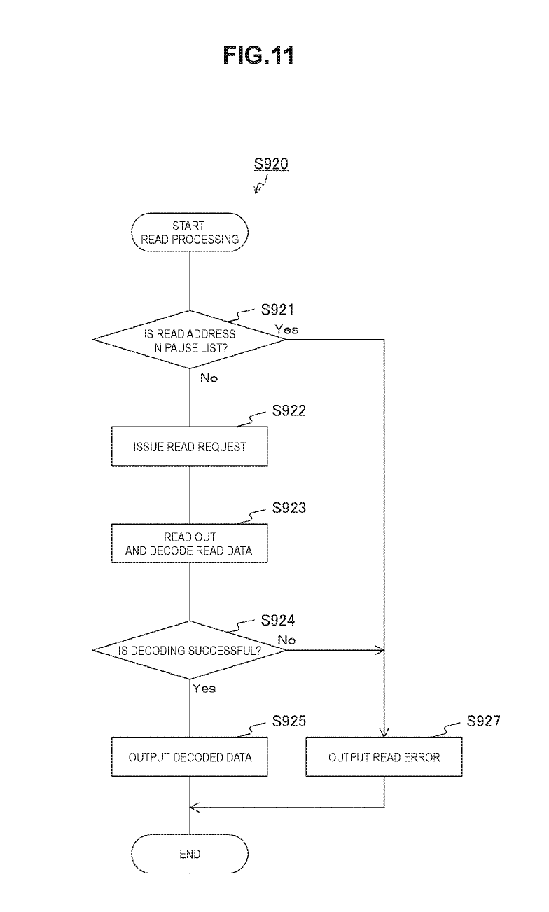

FIG. 11 is a flowchart illustrating an example of the read processing according to the first embodiment. The memory controller 300 determines whether the read address is in the read-out pause list (step S921). If the read address is not in the read-out pause list (No in step S921), the memory controller 300 issues a read request and supplies it to the non-volatile memory 400 (step S922). Then, the memory controller 300 reads out the read data from the non-volatile memory 400 and decodes it (step S923), and then determines whether the decoding is successful (step S924). If the decoding is successful (Yes in step S924), then the memory controller 300 outputs the decoded original data to the host computer 100 (step S925).

If the read address is in the read-out pause list (Yes in step S921), or if the decoding fails (No in step S924), the memory controller 300 outputs the status of the read error to the host computer 100 (step S927). Subsequent to step S925 or S927, the memory controller 300 ends the read processing.

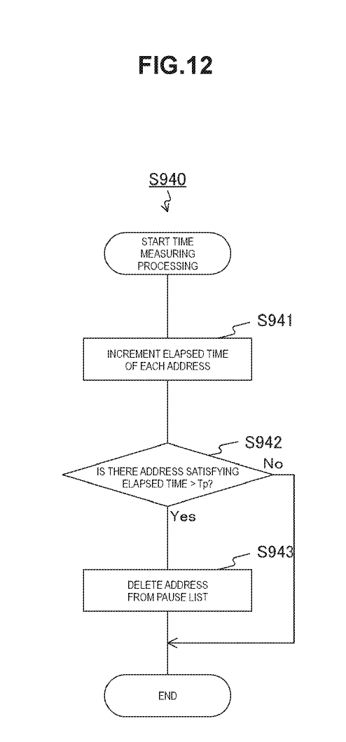

FIG. 12 is a flow chart illustrating an example of the time measuring processing according to the first embodiment. The memory controller 300 increments the elapsed time of each address in the read-out pause list (step S941). Then, the memory controller 300 determines whether the address where the elapsed time exceeds Tp is in the read-out pause list (step S942). If there is an address where the elapsed time exceeds Tp (Yes in step S942), the memory controller 300 invalidates the validity flag of the address and deletes it from the read-out pause list (step S943). If there is no address where the elapsed time exceeds Tp (No in step S942), or subsequent to step S943, the memory controller 300 ends the time measuring processing.

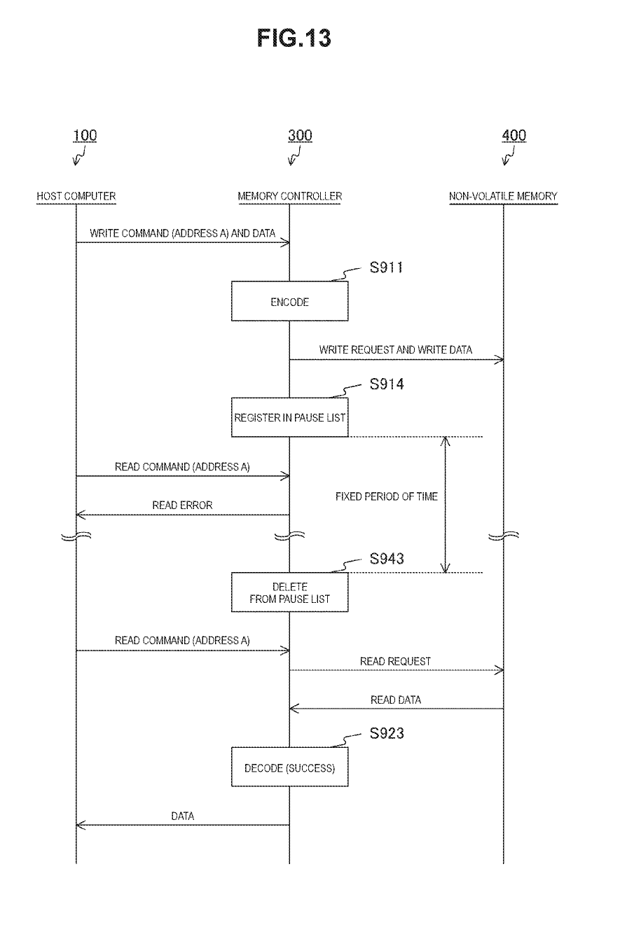

FIG. 13 is a sequence diagram illustrating an example of the operation of the memory system according to the first embodiment. If the host computer 100 supplies a write command, which designates an address A and data, to the memory controller 300, the memory controller 300 encodes the data (step S911). Then, the memory controller 300 issues a write request and supplies the write request and the write data to the non-volatile memory 400. In addition, the memory controller 300 registers the address A in the read-out pause list (step S914).

If the host computer 100 supplies the read command designating the address A to the memory controller 300 within a fixed period of time after the writing of data, the memory controller 300 returns the read error without performing read access.

Then, if the fixed period of time passes, the memory controller 300 deletes the address A from the read-out pause list (step S943). Then, if the host computer 100 supplies the read command designating the address A to the memory controller 300, the memory controller 300 issues a read request and reads out the read data from the non-volatile memory 400. The memory controller 300 decodes the read data (step S923). If the decoding is successful, the memory controller 300 outputs the decoded data to the host computer 100.

As described above, according to the first embodiment of the present technology, when the data is instructed to be read out, the memory controller 300 causes the read access to pause if it is within the fixed amount of time from the writing. This makes it possible to reduce unnecessary read access that may cause an error. Thus, it is possible to reduce progress of deterioration of the memory cell due to unnecessary read access.

### 2. Second Embodiment

According to the first embodiment described above, the memory controller 300 performs the read access only the case where the fixed amount of time during which the random telegraph noise is expected to occur passes when the data is instructed to be read out. However, the time during which the random telegraphic noise occurs is not limited to the fixed amount of time, and the error may be difficult to be eliminated even if the fixed amount of time passes. Thus, when the elapsed time exceeds the fixed amount of time, the memory controller 300 may perform the read access to perform error correction even if a read command is not issued. The success or failure of this error correction allows the memory controller 300 to determine whether the error is eliminated at the lapse of the fixed amount of time. The second embodiment differs from the first embodiment in that a memory controller 300 according to the second embodiment performs the read access even when a read command is not issued on condition that the elapsed time exceeds the fixed amount of time.

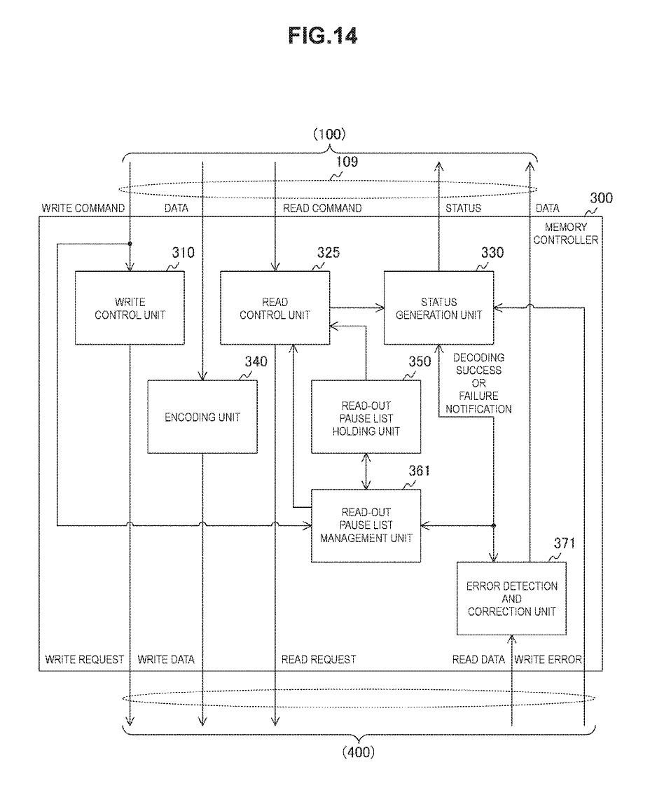

FIG. 14 is a block diagram illustrating a functional configuration example of the memory controller 300 according to the second embodiment. The second embodiment differs from the first embodiment in that the memory controller 300 includes a read control unit 325 instead of the read control unit 320. In addition, the second embodiment differs from the first embodiment in that the memory controller 300 includes a read-out pause list management unit 361 and an error detection and correction unit 371 instead of the read-out pause list management unit 360 and the error detection and correction unit 370, respectively.

In the case where an address whose corresponding elapsed time exceeds Tp exists, the read-out pause list management unit 361 deletes the address from the read-out pause list, issues a read command designating the address, and supplies it to the read control unit 325. In addition, when the address is deleted, the read-out pause list management unit 361 instructs the error detection and correction unit 371 not to output the decoded data to the host computer 100.

The read control unit 325, when receiving the read command from the read-out pause list management unit 361, issues a read request and supplies it to the non-volatile memory 400.

In the case where there is an instruction from the read-out pause list management unit 361, the error detection and correction unit 371 only notifies the host computer 100 of whether the decoding succeeds or fails without outputting the decoded data to the host computer 100.

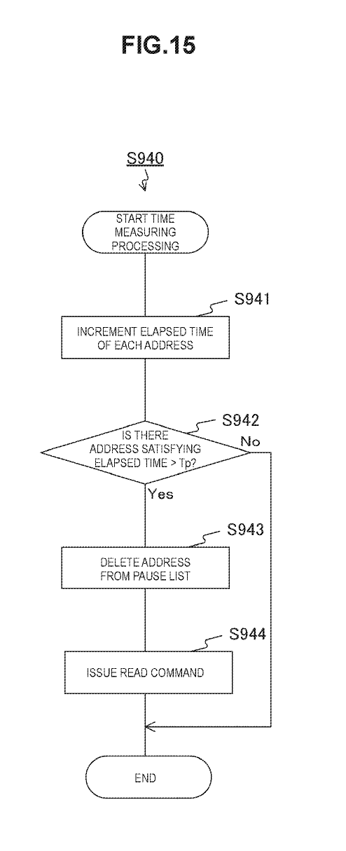

FIG. 15 is a flowchart illustrating an example of the time measuring processing according to the second embodiment. The time measuring processing according to the second embodiment differs from that of the first embodiment in that step S944 is further executed.

The memory controller 300 deletes the address from the read-out pause list (step S943), and then issues the read command designating the address (step S944). If there is no address whose elapsed time exceeds Tp (No in step S942) or subsequent to step S944, the memory controller 300 ends the time measuring processing.

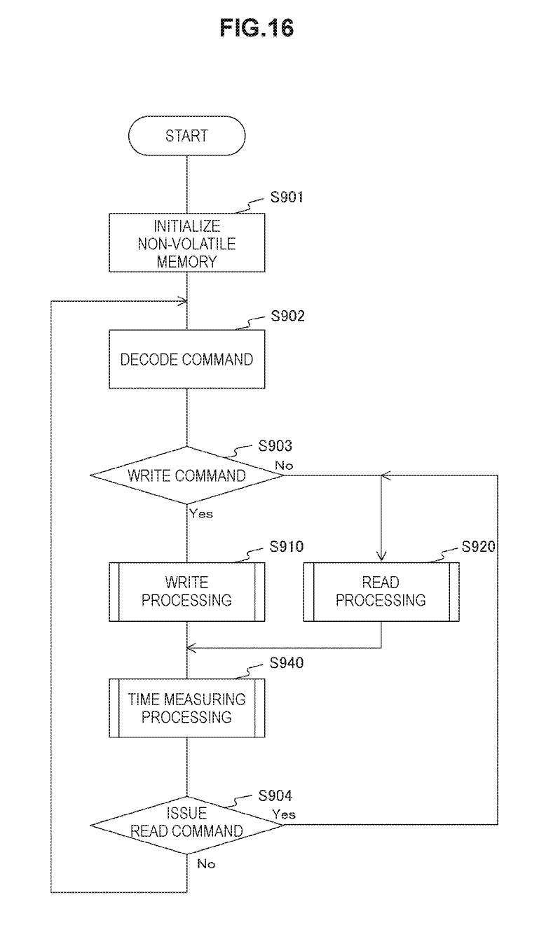

FIG. 16 is a flowchart illustrating an example of the operation of the memory controller 300 according to the second embodiment. The operation of the memory controller 300 according to the second embodiment differs from that of the first embodiment in that step S904 is further executed.

The memory controller 300 determines whether the read command is issued in the time measuring processing (step S904), subsequent to the time measuring processing (step S940). If the read command is issued (Yes in step S904), the memory controller 300 executes the read processing (step S920). On the other hand, if the read command is not issued (No in step S904), then the memory controller 300 returns to step S902.

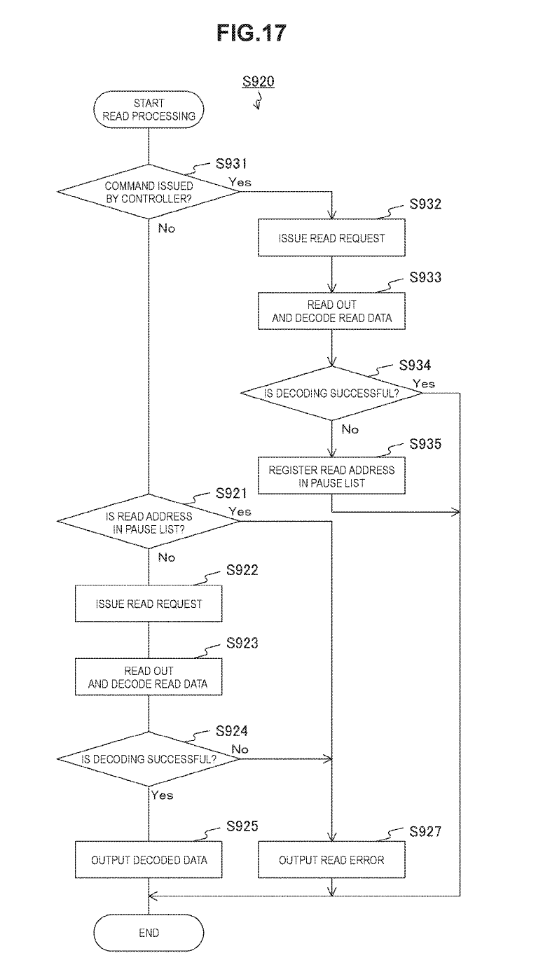

FIG. 17 is a flowchart illustrating an example of the read processing according to the second embodiment. The read processing according to the second embodiment differs from that of the first embodiment in that steps S931 to S935 are further executed.

The memory controller 300 determines whether the read command is a command that the memory controller 300 itself issues (step S931). If the read command is not a command that the memory controller itself issues (No in step S931), the memory controller 300 executes steps S921 to S925 and S927.

On the other hand, if the read command is a command that the memory controller 300 itself issues (Yes in step S931), the memory controller 300 issues a read request (step S932), reads out the read data, and decodes it (step S933). The memory controller 300 determines whether the decoding is successful (step S934). If the decoding fails (No in step S934), the memory controller 300 registers the read address in the read-out pause list (step S935). If the decoding is successful (Yes in step S934), or subsequent to step S935, the memory controller 300 ends the read processing.

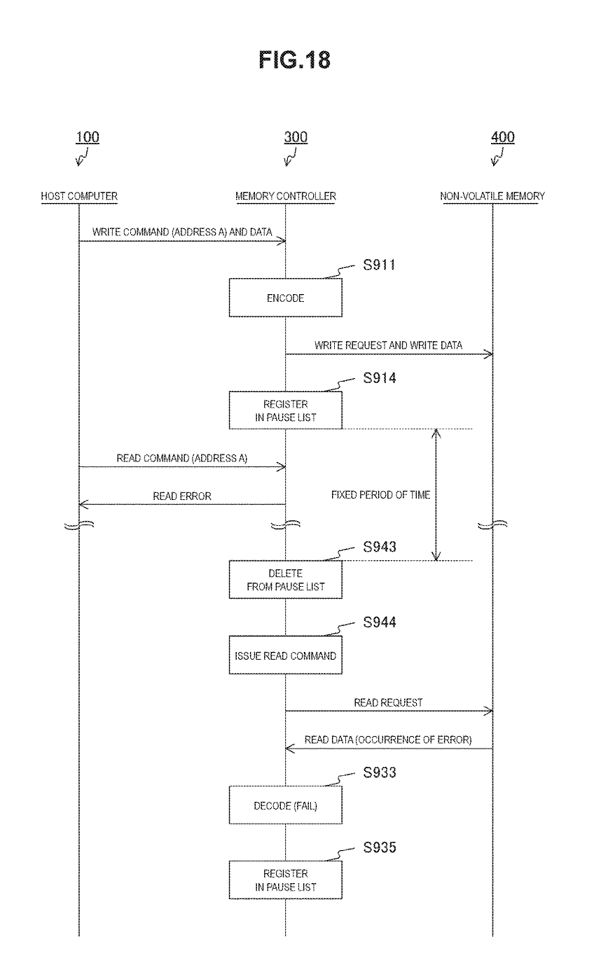

FIG. 18 is a sequence diagram illustrating an example of the operation of the memory system according to the second embodiment. If the memory controller 300 deletes the address A from the read-out pause list after the lapse of a fixed period of time (step S943), the memory controller 300 itself issues a read command (step S944. The memory controller 300 issues a read request and reads out the read data from a non-volatile memory 400. Then, the memory controller 300 decodes the read data (step S933). If the decoding fails, the memory controller 300 registers the address again in the read-out pause list (step S935).

As described above, according to the second embodiment of the present technology, the memory controller 300 reads out the read data to perform the error correction when the time elapsed from the writing exceeds the fixed amount of time, and thus it is possible to determine whether an error is eliminated after the lapse of the fixed amount of time.

### 3. Third Embodiment

According to the first embodiment described above, the memory controller 300 starts the time measurement at the timing when data is written. However, the number of errors caused by the random telegraph noise in a code word is not fixed, and there may be cases where errors of the number that is only just enough for the error correction to succeed occur. In this case, the read access is unnecessary to pause. Thus, the memory controller 300 may start time measurement at the timing when the error correction fails and a read error occurs, rather than start the time measurement at the time of successful error correction. This eliminates the necessity of causing the read access to pause in the case where errors of the number that is only just enough for the error correction to succeed occur, thereby improving the access efficiency. A memory controller 300 according to the third embodiment differs from that of the first embodiment in that the time measurement starts at the timing when a read error occurs.

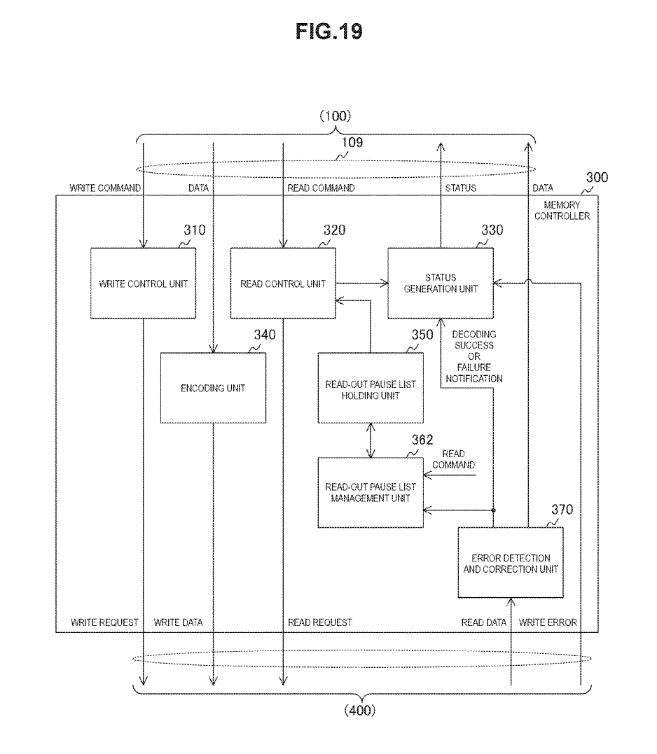

FIG. 19 is a block diagram illustrating a functional configuration example of the memory controller 300 according to the third embodiment. The third embodiment differs from the first embodiment in that the memory controller 300 according to the third embodiment includes a read-out pause list management unit 362 instead of the read-out pause list management unit 360.

The read-out pause list management unit 362 registers the address designated by the read command in the read-out pause list in the case where the error correction of read data fails, which is different from the first embodiment. This allows the time measurement to start at a timing at which a read error occurs.

Moreover, although the read-out pause list management unit 362 starts the time measurement at the timing when the error correction fails, the time measurement may start at the timing when an error is detected, regardless of success or failure of error correction. However, in the configuration in which the time measurement starts even if the error correction is successful, control to cause the read access to pause over a fixed amount of time is performed more frequently, which may lead to a decrease in the access efficiency. Thus, the memory controller 300 is preferable to start the time measurement at the timing when the error correction fails.

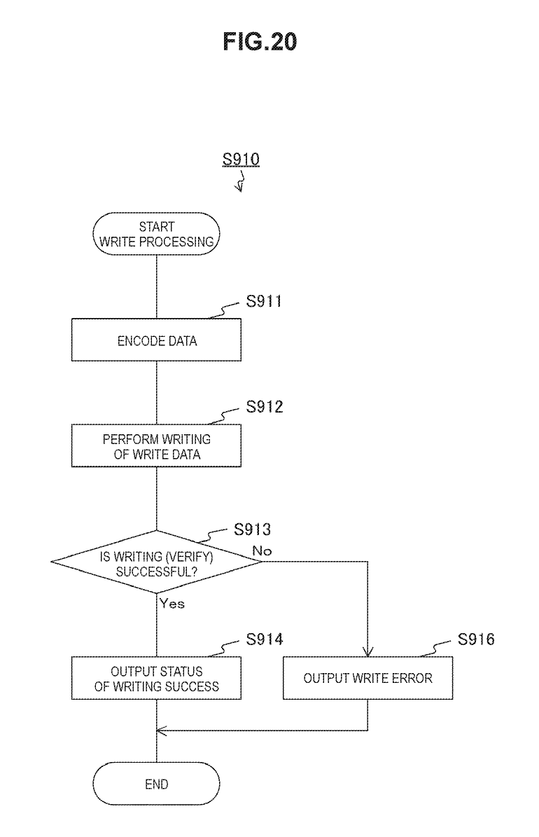

FIG. 20 is a flowchart illustrating an example of the write process according to the third embodiment. The write processing according to the third embodiment differs from that of the first embodiment in that the registration of a write address in a read-out pause list (step S915) is not executed.

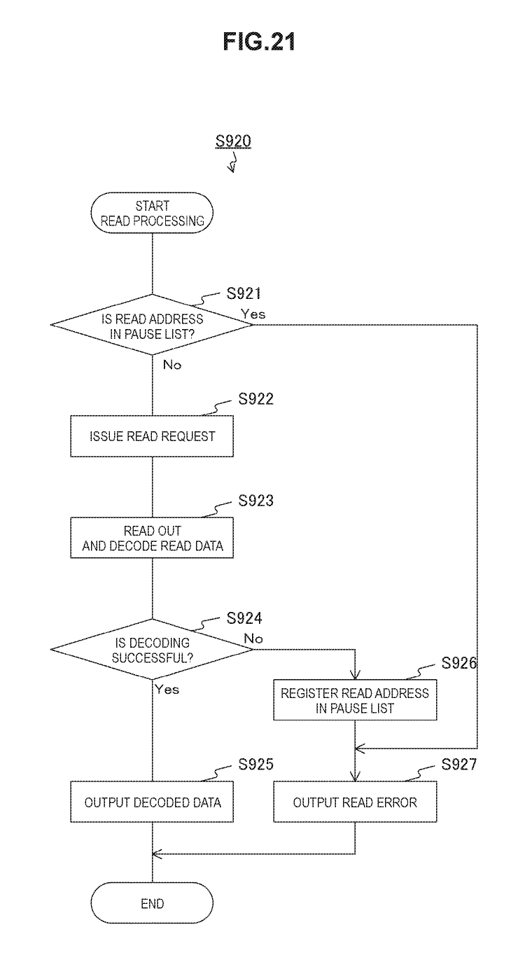

FIG. 21 is a flowchart illustrating an example of the read processing according to the third embodiment. The read processing according to the third embodiment differs from that of the first embodiment in that step S926 is further executed.

If the decoding fails (No in step S924), the memory controller 300 registers the read address in the read-out pause list (step S926). In addition, if the read address is not in the read-out pause list (No in step S921), or subsequent to step S926, the memory controller 300 outputs a read error (step S927).

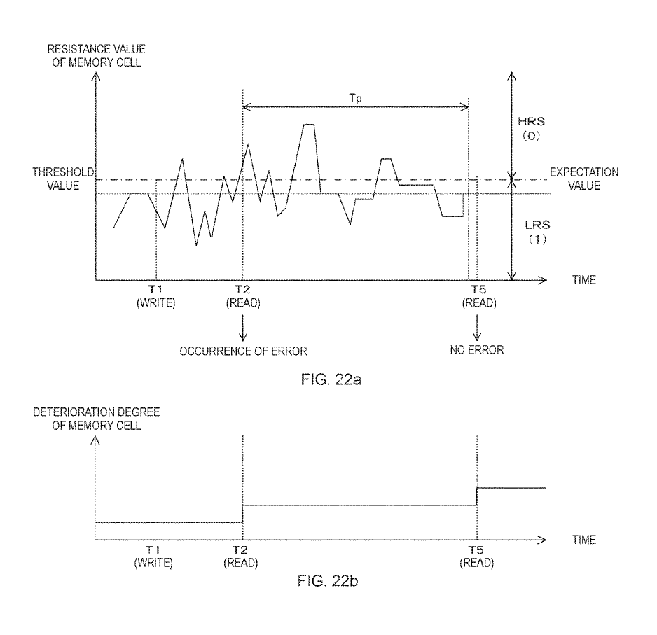

FIG. 22 is a graph showing an example of a variation in resistance values and deterioration degree of the memory cell with the lapse of time in the third embodiment. The portion a of this figure is a graph showing an example of a variation in resistance values of the memory cell with the lapse of time. In the portion a of this figure, the vertical axis represents the resistance value of the memory cell, and the horizontal axis represents time.

It is assumed that a read error occurs due to random telegraph noise at timing T2 after timing T1 at which the writing is performed. In this case, the memory controller 300 measures the time elapsed from the timing T2. If the read command is received before the elapsed time exceeds Tp, the memory controller 300 returns the status of the read error to the host computer 100 without performing the read access to the memory cell.

On the other hand, if the read command is received at the timing T5 when the elapsed time exceeds Tp, the memory controller 300 reads out the read data from the memory cell and decodes it. At the timing T5, the random telegraph noise is eliminated, and thus no error is detected.

The portion b of FIG. 22 is a graph showing an example of a variation in the deterioration degree of the memory cell with the elapse of time in the first embodiment. In the portion b of this figure, the vertical axis represents the deterioration degree of the memory cell, and the horizontal axis represents time. The read access is performed at each of the timings T2 and T5, and so the deterioration degree of the memory cell is relatively high at these timings.

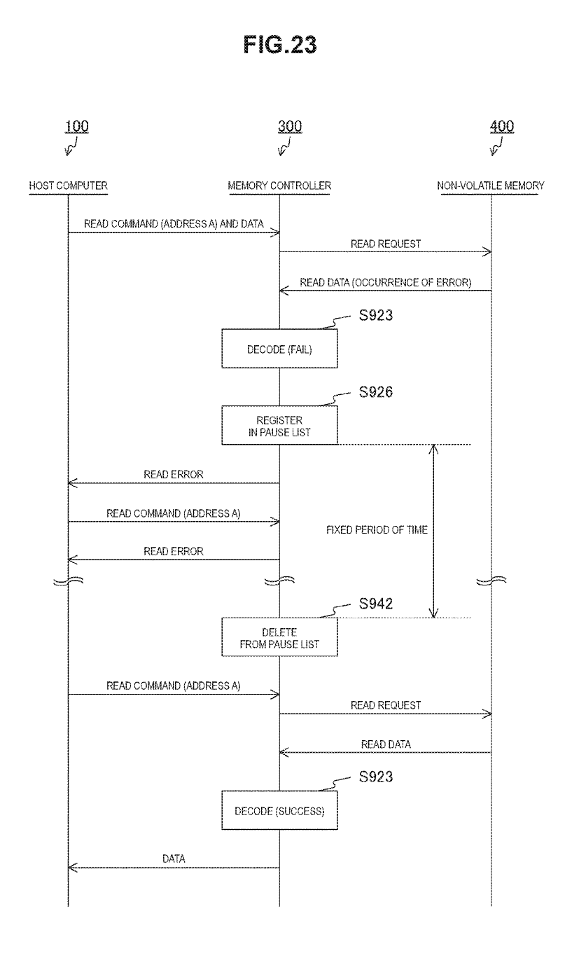

FIG. 23 is a sequence diagram illustrating an example of the operation of the memory system according to the third embodiment.

The memory controller 300 issues a read command in accordance with the read command that designates the address A, and reads out the read data. Then, the memory controller 300 decodes the read data (step S923). If the decoding fails, the memory controller 300 registers the read address in the read-out pause list (step S926). In addition, the memory controller 300 outputs a read error.

As described above, according to the third embodiment of the present technology, the memory controller 300 starts the time measurement at the timing when the error correction fails, and so, if the number of errors is small, the read access does not pause, which leads to improvement of the access efficiency.

### 4. Fourth Embodiment

In the third embodiment described above, the memory controller 300 performs the read access only in the case where a fixed amount of time passes from the writing when the data is instructed to be read out. However, in the third embodiment, the read access may be performed even if the read command is not issued after the fixed amount of time passes, which is similar to the second embodiment. A memory controller 300 according to the fourth embodiment differs from that of the third embodiment in that the read access is performed even if a read command is not issued on condition that the elapsed time exceeds the fixed amount of time.

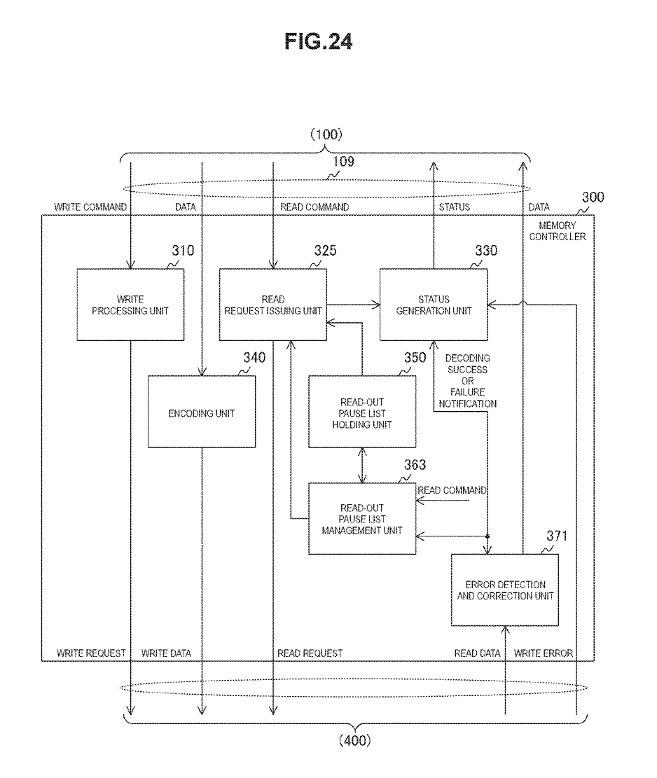

FIG. 24 is a block diagram illustrating a functional configuration example of the memory controller 300 according to the fourth embodiment. The fourth embodiment differs from the third embodiment in that the memory controller 300 according to the fourth embodiment includes a read-out pause list management unit 363 instead of the read-out pause list management unit 360.

The read-out pause list management unit 363 registers the address designated by the read command in the read-out pause list when the error correction of the read data fails, which is different from the read-out pause list management unit 362 of the third embodiment.

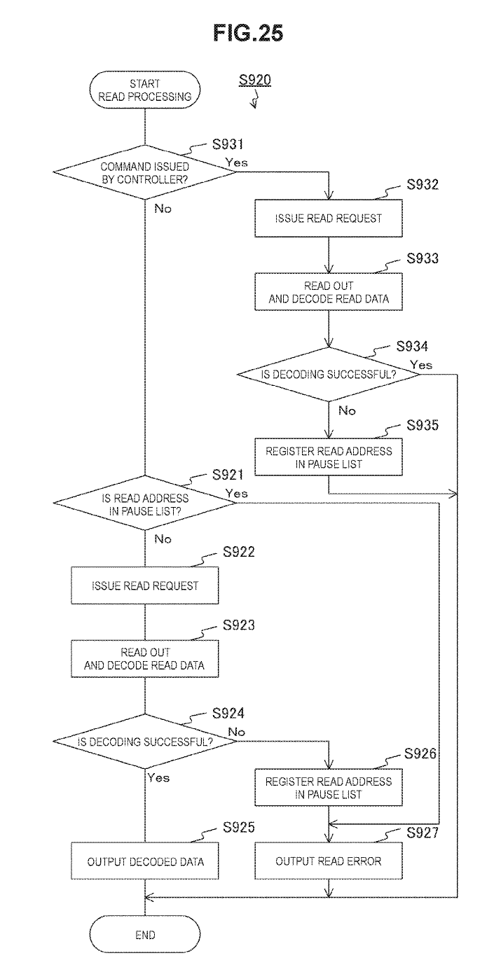

FIG. 25 is a flowchart illustrating an example of the read processing according to the fourth embodiment. The read processing according to the fourth embodiment differs from that of the third embodiment in that steps S931 to S935 are further executed.

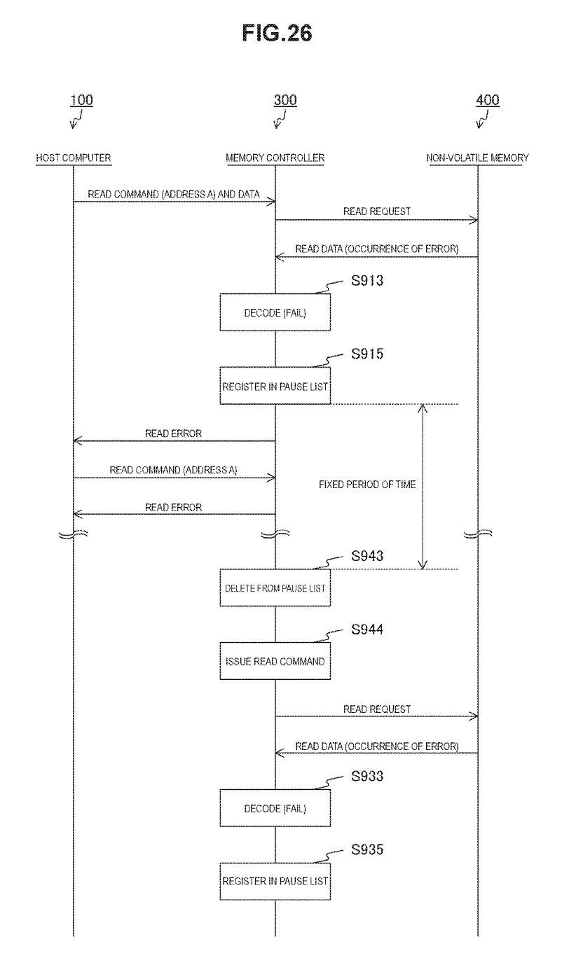

FIG. 26 is a sequence diagram illustrating an example of the operation of the memory system according to the fourth embodiment. If the memory controller 300 deletes the address A from the read-out pause list after a lapse of a fixed period of time (step S943), the memory controller 300 itself issues a read command (step S944. The memory controller 300 issues a read request and reads out the read data from the non-volatile memory 400. Then, the memory controller 300 decodes the read data (step S933). If the decoding fails, the memory controller 300 registers the address again in the read-out pause list (step S935).

As described above, according to the fourth embodiment of the present technology, the memory controller 300 reads out the read data and performs the error correction if the time elapsed from when the error correction fails exceeds the fixed amount of time. Thus, it is possible to determine whether an error is eliminated after a lapse of the fixed amount of time.

The above-described embodiments are examples for embodying the present technology, and matters in the embodiments each have a corresponding relationship with disclosure-specific matters in the claims. Likewise, the matters in the embodiments and the disclosure-specific matters in the claims denoted by the same names have a corresponding relationship with each other. However, the present technology is not limited to the embodiments, and various modifications of the embodiments may be embodied in the scope of the present technology without departing from the spirit of the present technology.

The processing sequences that are described in the embodiments described above may be handled as a method having a series of sequences or may be handled as a program for causing a computer to execute the series of sequences and recording medium storing the program. Examples of the recording medium include compact disc (CD), minidisc (MD), and digital versatile disc (DVD), memory card, and Blu-ray disc (registered trademark).

In addition, the effects described in the present specification are not limiting but are merely examples, and there may be other effects.

Additionally, the present technology may also be configured as below.
(1)

A memory controller including:

a time measuring unit configured to measure time elapsed from predetermined timing on an address where data is written;

an elapsed time determination unit configured to determine whether the elapsed time exceeds a fixed amount of time upon receiving an instruction to read out the data from the address; and

a read control unit configured to cause reading out the data from the address to pause in a case where the elapsed time is determined not to exceed the fixed amount of time.
(2)

The memory controller according to (1), further including:

a holding unit configured to hold the address and the elapsed time,

wherein the time measuring unit measures the elapsed time and causes the holding unit to hold the address and the elapsed time, and

the elapsed time determination unit reads out the address and the elapsed time from the holding unit.
(3)

The memory controller according to (1) or (2),

wherein the time measuring unit measures the elapsed time by setting timing of writing the data to the address as the predetermined timing.
(4)

The memory controller according to (3), further including:

an error detection and correction unit configured to detect an error of the data read out from the address and to correct the error,

wherein the time measuring unit issues the instruction to read out the data from the address in a case where the elapsed time exceeds the fixed amount of time,

the read control unit reads out the data from the address in a case where the elapsed time is determined to exceed the fixed amount of time or a case where the time measuring unit issues the instruction to read out the data, and

the time measuring unit measures the elapsed time by setting the timing of writing the data to the address or timing at which the error fails to be corrected as the predetermined timing.
(5)

The memory controller according to (1), further including:

an error detection and correction unit configured to detect an error of the data read out from the address and to correct the error,

wherein the time measuring unit measures the elapsed time by setting timing at which the error fails to be corrected as the predetermined timing.
(6)

The memory controller according to (5),

wherein the time measuring unit issues the instruction to read out the data from the address in a case where the elapsed time exceeds the fixed amount of time, and

the read control unit reads out the data from the address in a case where the elapsed time is determined to exceed the fixed amount of time or a case where the time measuring unit issues the instruction to read out the data.
(7)

The memory controller according to any of (1) to (6), further including:

a read-error output unit configured to output a read error in the case where the elapsed time is determined not to exceed the fixed amount of time.
(8)

A memory system including:

a memory cell having an address assigned to the memory cell;

a time measuring unit configured to measure time elapsed from predetermined timing on the address where data is written;

an elapsed time determination unit configured to determine whether the elapsed time exceeds a fixed amount of time upon receiving an instruction to read out the data from the address; and

a read control unit configured to cause reading out the data from the address to pause in a case where the elapsed time is determined not to exceed the fixed amount of time.
(9)

A method of controlling a memory controller, the method including:

a time measurement step of measuring, by a time measuring unit, time elapsed from predetermined timing on an address where data is written;

an elapsed time determination step of determining, by an elapsed time determination unit, whether the elapsed time exceeds a fixed amount of time upon receiving an instruction to read out the data from the address; and

a read control step of causing reading out of the data from the address to pause in a case where the elapsed time is determined not to exceed the fixed amount of time.

### REFERENCE SIGNS LIST

100 host computer
200 storage
300 memory controller
301 host interface
302 RAM
303 CPU
304 ECC processing unit
305 ROM
306, 450 Bus
307 memory interface
310 write control unit
320, 325 read control unit
321 elapsed time determination unit
322 read request issuing unit
330 status generation unit
340 encoding unit
350 read-out pause list holding unit
360, 361, 362, 363 read-out pause list management unit
370, 371 error detection and correction unit
400 non-volatile memory
410 data buffer
420 memory cell array
430 driver
440 address decoder
460 control interface
470 memory control unit

1. A memory controller comprising:
a time measuring unit configured to measure time elapsed from predetermined timing on an address where data is written;
an elapsed time determination unit configured to determine whether the elapsed time exceeds a fixed amount of time upon receiving an instruction to read out the data from the address; and
a read control unit configured to cause reading out the data from the address to pause in a case where the elapsed time is determined not to exceed the fixed amount of time.

2. The memory controller according to claim 1, further comprising:
a holding unit configured to hold the address and the elapsed time,
wherein the time measuring unit measures the elapsed time and causes the holding unit to hold the address and the elapsed time, and
the elapsed time determination unit reads out the address and the elapsed time from the holding unit.

3. The memory controller according to claim 1,
wherein the time measuring unit measures the elapsed time by setting timing of writing the data to the address as the predetermined timing.

4. The memory controller according to claim 3, further comprising:
an error detection and correction unit configured to detect an error of the data read out from the address and to correct the error,
wherein the time measuring unit issues the instruction to read out the data from the address in a case where the elapsed time exceeds the fixed amount of time,
the read control unit reads out the data from the address in a case where the elapsed time is determined to exceed the fixed amount of time or a case where the time measuring unit issues the instruction to read out the data, and
the time measuring unit measures the elapsed time by setting the timing of writing the data to the address or timing at which the error fails to be corrected as the predetermined timing.

5. The memory controller according to claim 1, further comprising:
an error detection and correction unit configured to detect an error of the data read out from the address and to correct the error,
wherein the time measuring unit measures the elapsed time by setting timing at which the error fails to be corrected as the predetermined timing.

6. The memory controller according to claim 5,
wherein the time measuring unit issues the instruction to read out the data from the address in a case where the elapsed time exceeds the fixed amount of time, and
the read control unit reads out the data from the address in a case where the elapsed time is determined to exceed the fixed amount of time or a case where the time measuring unit issues the instruction to read out the data.

7. The memory controller according to claim 1, further comprising:
a read-error output unit configured to output a read error in the case where the elapsed time is determined not to exceed the fixed amount of time.

8. A memory system comprising:
a memory cell having an address assigned to the memory cell;
a time measuring unit configured to measure time elapsed from predetermined timing on the address where data is written;
an elapsed time determination unit configured to determine whether the elapsed time exceeds a fixed amount of time upon receiving an instruction to read out the data from the address; and
a read control unit configured to cause reading out the data from the address to pause in a case where the elapsed time is determined not to exceed the fixed amount of time.

9. A method of controlling a memory controller, the method comprising:
a time measurement step of measuring, by a time measuring unit, time elapsed from predetermined timing on an address where data is written;
an elapsed time determination step of determining, by an elapsed time determination unit, whether the elapsed time exceeds a fixed amount of time upon receiving an instruction to read out the data from the address; and
a read control step of causing reading out of the data from the address to pause in a case where the elapsed time is determined not to exceed the fixed amount of time.
